(19) United States
(12) Patent Application Publication
(10) Pub. No.: US 2023/0411579 A1
(43) Pub. Date: Dec. 21, 2023

(54) TILEABLE MICROLED DISPLAY

(71) Applicant: Lumileds LLC, San Jose, CA (US)

(72) Inventors: Brendan Jude MORAN, San Jose, CA (US); Wouter SOER, Utrecht (NL); Grigoriy BASIN, San Francisco, CA (US); Johannes Willem Herman Sillevis Smitt, San Jose, CA (US)

(73) Assignee: Lumileds LLC, San Jose, CA (US)

(21) Appl. No.: 18/207,917

(22) Filed: Jun. 9, 2023

Related U.S. Application Data
(63) Continuation-in-part of application No. 18/206,309, filed on Jun. 6, 2023.
(60) Provisional application No. 63/352,517, filed on Jun. 15, 2022.
(60) Provisional application No. 63/420,872, filed on Oct. 31, 2022.

(51) Int. Cl. H01L 33/62; H01L 25/16

(52) U.S. Cl. CPC H01L 33/62; H01L 25/167

(57) ABSTRACT

Display devices comprise an optionally transparent display area that extends to one or more physical boundaries (edges) of the device. The display area may be located on a front surface of the display device, and the physical boundaries of the device to which the display area extends may be formed by physical sides of the device that intersect with the front surface to define part of a perimeter of the front surface. The display area may comprise a microLED array that extends with the display area to edges of the device. Power and/or control electronics for the display device may be located adjacent the display area but away from the edges of the display device to which the display area extends. Two or more such display devices can be arranged (i.e., tiled) with their display areas adjacent, in contact, and facing the same direction to form an extended continuous microLED display area spanning the display areas of the two or more display devices.

### CROSS-REFERENCE TO RELATED APPLICATIONS

This application claims priority to U.S. Provisional Patent Application 63/352,517 filed 15 Jun. 2022, U.S. Provisional Patent Application 63/420,872 filed 31 Oct. 2022, and U.S. patent application Ser. No. 18/206,309 filed 6 Jun. 2023, each of which is incorporated herein by reference in its entirety.

### FIELD OF THE INVENTION

The invention relates generally to LEDs, pcLEDs, LED and pcLED arrays, displays comprising LED or pcLED arrays, and visualization systems comprising such displays.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Inorganic LEDs and pcLEDs have been widely used to create different types of displays, for example augmented-reality (AR) displays, virtual-reality (VR) displays, mixed-reality (MR) displays (AR, VR, and MR systems referred to herein as visualization systems), smart glasses and displays for mobile phones, smart watches, monitors and TVs. Individual LEDs or pcLEDs in these architectures can have an area of a few square millimeters down to a few square micrometers (e.g., microLEDs) depending on the display size and its pixel per inch requirements.

### SUMMARY

This specification discloses display devices having a display area that extends to one or more physical boundaries (edges) of the device. The display area may for example be located on a front surface of the display device, and the physical boundaries of the device to which the display area extends may be formed by physical sides of the device that intersect with the front surface to define part of a perimeter of the front surface. Two or more such display devices can be arranged (i.e., tiled) with their display areas adjacent, in contact, and facing the same direction to form an extended continuous display area spanning the display areas of the two or more display devices. Power and/or control electronics for the display device may be located, for example, adjacent the display area but away from the physical boundaries of the display device to which the display area extends.

The display device display areas may comprise microLED arrays that extend with the display area to physical boundaries of the device. Combining two or more display devices as described above thus provides an extended continuous microLED array spanning the display areas of the two or more display devices. The microLEDs in the array on a display device may for example be spaced with a center-to-center pitch distance L, with the array of microLEDs extending to a distance L/2 of a physical boundary of the display device. For two such display devices combined as just described, the extended continuous microLED array spanning the display device areas of the two display devices can maintain a center-to-center pitch distance of L for adjacent microLEDs as the array crosses from one display device display area to the other.

The display areas of the display devices may be transparent. As used in this specification, transparent is intended to mean that the display area allows light to pass through so that objects behind the display area can be distinctly seen. This may be accomplished for example using sufficiently sparse arrays (e.g., pitch L of≥80 μm) of sufficiently small microLEDs (e.g., side lengths of 2 microns to 20 microns) arranged on a transparent substrate, with the control and power electronics arranged adjacent to the microLED array rather than behind it. Conductive paths (e.g., electrical leads) providing power and/or control signals from the power/control electronics area of a display device to the microLED arrays may be, for example, transparent or sufficiently thin (e.g., width≤30 μm) to not obstruct a view through the microLED array. Such a transparent display area may be, for example, at least 65% transmissive to visible light or at least 85% transmissive to visible light.

An advantage to such tileable display devices is that they may be used to construct a large continuous (e.g., constant pitch) and optionally transparent microLED display from two or more smaller microLED arrays. This can overcome limitations on the size to which a single microLED array may be manufactured.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs. FIG. 2C shows a schematic top view of an LED wafer from which LED arrays such as those illustrated in FIGS. 2A and 2B may be formed.

FIG. 3 schematically illustrates an example display system.

FIG. 4 shows a block diagram of an example visualization system.

FIG. 5A shows a schematic plan view of an example tileable display device.

FIG. 5B schematically shows a cross-sectional side view of the example display device of FIG. 5A.

FIG. 6A shows a schematic plan view of an example display system comprising six of the display devices of FIG. 5A and FIG. 5B.

FIG. 6B shows an expanded view of a region of the example display system of FIG. 6A.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

FIG. 1 shows an example of an individual pcLED 100 comprising a light emitting semiconductor diode (LED) structure 102 disposed on a substrate 104, and a phosphor layer 106 (which may also be referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications from the pcLED. Phosphor layers may for example comprise phosphor particles dispersed in or bound to each other with a binder material or be or comprise a sintered ceramic phosphor plate.

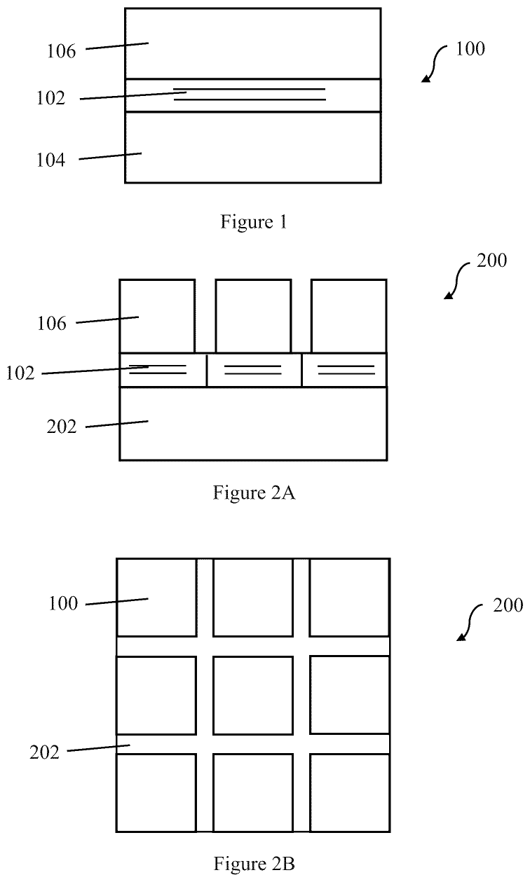

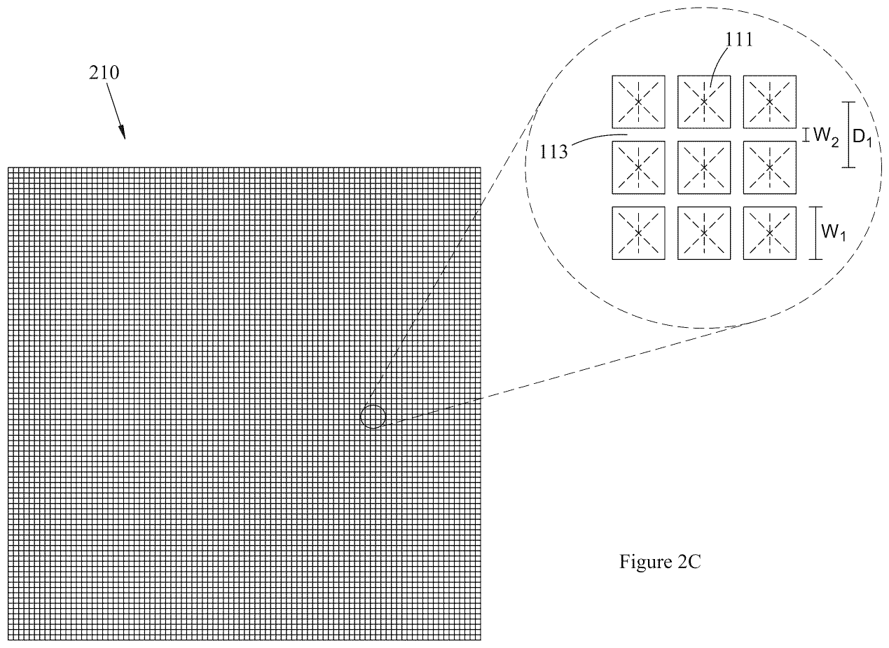

FIGS. 2A-2B show, respectively, cross-sectional and top views of an array 200 of pcLEDs 100 including phosphor layers 106 disposed on a substrate 202. Such an array may include any suitable number of pcLEDs arranged in any suitable manner. An array of LED or pcLEDs may be formed monolithically on a shared substrate, but alternatively an array of LEDs or pcLEDs may be formed from individual mechanically separate LEDs or pcLEDs. Substrate 202 may optionally comprise CMOS circuitry for driving the LEDs and may be formed from any suitable materials.

Although FIGS. 2A-2B show a three-by-three array of nine pcLEDs, such arrays may include for example tens, hundreds, or thousands of LEDs or pcLEDs. Individual LEDs or pcLEDs may have widths (e.g., side lengths) in the plane of the array of, for example, less than or equal to 1 millimeter (mm), less than or equal to 500 microns, less than or equal to 100 microns, less than or equal to 50 microns, or less than or equal to 10 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns. Although the illustrated examples show rectangular LEDs or pcLEDs arranged in a symmetric matrix, the LEDs or pcLEDs and the array may have any suitable shape or arrangement and need not all be of the same shape or size. For example, LEDs or pcLEDs located in central portions of an array may be larger than those located in peripheral portions of the array. Alternatively, LEDs or pcLEDs located in central portions of an array may be smaller than those located in peripheral portions of the array.

FIG. 2C shows a schematic top view of a portion of an LED wafer 210 from which LED arrays such as those illustrated in FIGS. 2A and 2B may be formed. FIG. 2C also shows an enlarged 3×3 portion of the wafer. In the example wafer individual LEDs or pcLEDs 111 having side lengths (e.g., widths) of W₁ are arranged as a square matrix with neighboring LEDs or pcLEDs having a center-to-center distances D₁ and separated by lanes 113 having a width W₂. W₁ may be, for example, less than or equal to 1 millimeter (mm), less than or equal to 500 microns, less than or equal to 100 microns, less than or equal to 50 microns, or less than or equal to 10 microns. W₂ may be, for example, hundreds of microns, less than or equal to 100 microns, less than or equal to 50 microns, less than or equal to 10 microns, or less than or equal to 5 microns. D₁=W₁+W₂.

An array may be formed, for example, by dicing wafer 210 into individual LEDs or pcLEDs and arranging the dice on a substrate. Alternatively, an array may be formed from the entire wafer 210, or by dividing wafer 210 into smaller (e.g., monolithic) arrays of LEDs or pcLEDs.

LEDs or pcLEDs having dimensions in the plane of the array (e.g., side lengths) of less than or equal to about 50 microns are typically referred to as microLEDs, and an array of such microLEDs may be referred to as a microLED array.

In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light.

The individual LEDs or pcLEDs in an array may be individually operable (addressable) and/or may be operable as part of a group or subset of (e.g., adjacent) LEDs or pcLEDs in the array.

An array of LEDs or pcLEDs, or portions of such an array, may be formed as a segmented monolithic structure in which individual LEDs or pcLEDs are electrically isolated or partially electrically isolated from each other by trenches and/or insulating material, but the electrically isolated or partially electrically isolated segments remain physically connected to each other by other portions of the semiconductor structure. For example, in such a monolithic structure the active region and a first semiconductor layer of a first conductivity type (n or p) on one side of the active region may be segmented, and a second unsegmented semiconductor layer of the opposite conductivity type (p or n) positioned on the opposite side of the active region from the first semiconductor layer. The second semiconductor layer may then physically and electrically connect the segmented structures to each other on one side of the active region, with the segmented structures otherwise electrically isolated from each other and thus separately operable as individual LEDs.

An LED or pcLED array may therefore be or comprise a monolithic multicolor matrix of individually operable LED or pcLED light emitters. The LEDs or pcLEDs in the monolithic array may for example be microLEDs as described above.

A single individually operable LED or pcLED or a group of adjacent such LEDs or pcLEDs may correspond to a single pixel (picture element) in a display. For example, a group of three individually operable adjacent LEDs or pcLEDs comprising a red emitter, a blue emitter, and a green emitter may correspond to a single color-tunable pixel in a display. In some variations a group of six individually operable adjacent LEDs or pcLEDs comprising two red emitters, two blue emitters, and two green emitters correspond to a single-color tunable pixel in a display, with the additional red, blue, and green emitters providing redundancy in case the other emitter of the same color fails.

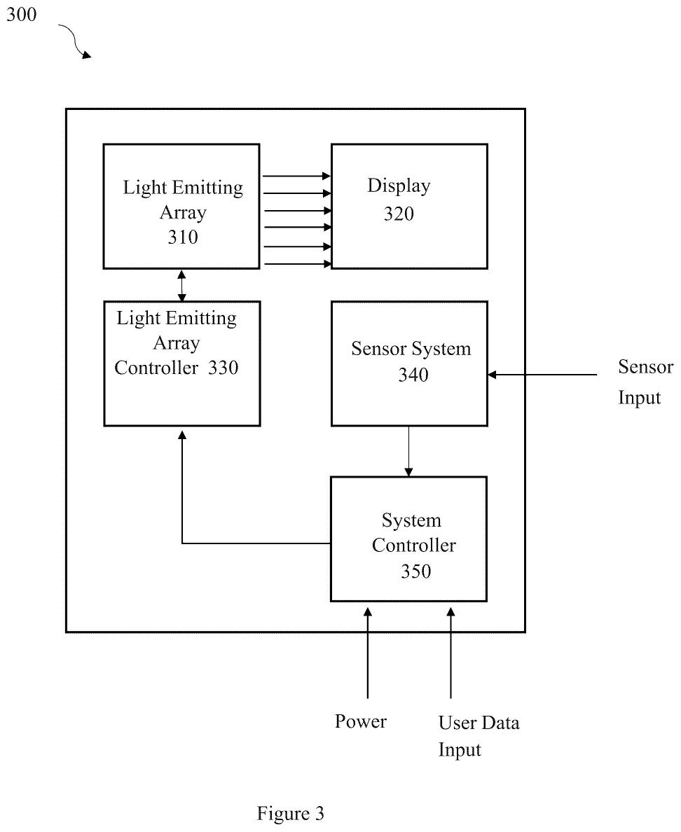

FIG. 3 schematically illustrates an example display system 300 that includes an array 310 of LEDs or pcLEDs that are individually operable or operable in groups, a display 320, a light emitting array controller 330, a sensor system 340, and a system controller 350. Array 310 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Similarly, to provide redundancy in the event of a defective LED or pcLED, a group of six individually operable adjacent LEDs or pcLEDs comprising two red emitters, two blue emitters, and two green emitters may correspond to a single color-tunable pixel in the display Array 310 can be used to project light in graphical or object patterns that can for example support AR/VR/MR systems.

Sensor input is provided to the sensor system 340, while power and user data input is provided to the system controller 350. In some embodiments modules included in system 300 can be compactly arranged in a single structure, or one or more elements can be separately mounted and connected via wireless or wired communication. For example, array 310, display 320, and sensor system 340 can be mounted on a headset or glasses, with the light emitting array controller and/or system controller 350 separately mounted.

System 300 can incorporate a wide range of optics (not shown) to couple light emitted by array 310 into display 320. Any suitable optics may be used for this purpose.

Sensor system 340 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input through the sensor system can include detected touch or taps, gestural input, or control based on headset or display position.

In response to data from sensor system 340, system controller 350 can send images or instructions to the light emitting array controller 330. Changes or modification to the images or instructions can also be made by user data input, or automated data input as needed. User data input can include but is not limited to that provided by audio instructions, haptic feedback, eye or pupil positioning, or connected keyboard, mouse, or game controller.

As noted above, AR, VR, and MR systems may be more generally referred to as examples of visualization systems. In a virtual reality system, a display can present to a user a view of scene, such as a three-dimensional scene. The user can move within the scene, such as by repositioning the user's head or by walking. The virtual reality system can detect the user's movement and alter the view of the scene to account for the movement. For example, as a user rotates the user's head, the system can present views of the scene that vary in view directions to match the user's gaze. In this manner, the virtual reality system can simulate a user's presence in the three-dimensional scene. Further, a virtual reality system can receive tactile sensory input, such as from wearable position sensors, and can optionally provide tactile feedback to the user.

In an augmented reality system, the display can incorporate elements from the user's surroundings into the view of the scene. For example, the augmented reality system can add textual captions and/or visual elements to a view of the user's surroundings. For example, a retailer can use an augmented reality system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the augmented reality system can position a virtual chair in a room. The user can stand in the room on a front side of the virtual chair location to view the front side of the chair. The user can move in the room to an area behind the virtual chair location to view a back side of the chair. In this manner, the augmented reality system can add elements to a dynamic view of the user's surroundings.

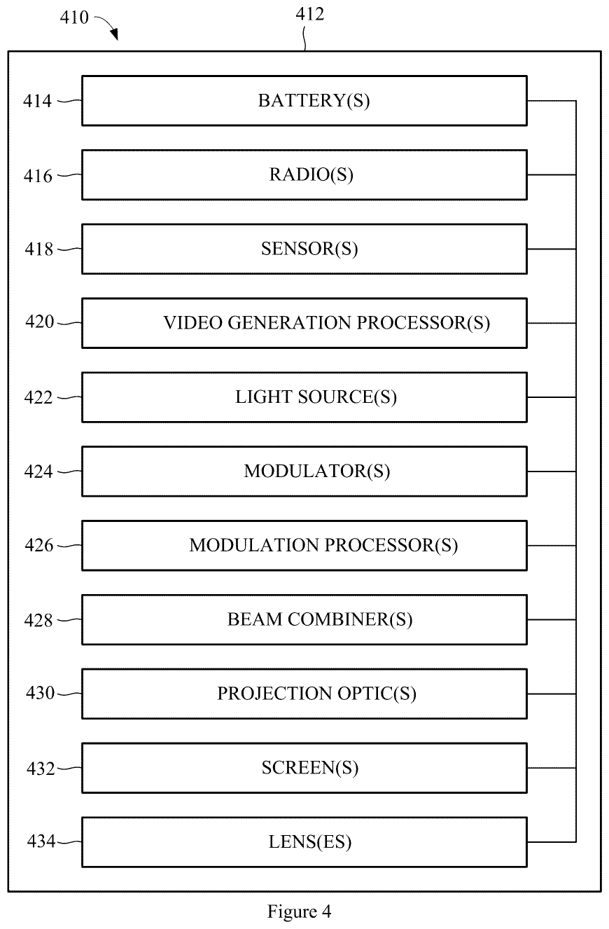

FIG. 4 shows a generalized block diagram of an example visualization system 410. The visualization system 410 can include a wearable housing 412, such as a headset or goggles. The housing 412 can mechanically support and house the elements detailed below. In some examples, one or more of the elements detailed below can be included in one or more additional housings that can be separate from the wearable housing 412 and couplable to the wearable housing 412 wirelessly and/or via a wired connection. For example, a separate housing can reduce the weight of wearable goggles, such as by including batteries, radios, and other elements. The housing 412 can include one or more batteries 414, which can electrically power any or all of the elements detailed below. The housing 412 can include circuitry that can electrically couple to an external power supply, such as a wall outlet, to recharge the batteries 414. The housing 412 can include one or more radios 416 to communicate wirelessly with a server or network via a suitable protocol, such as WiFi.

The visualization system 410 can include one or more sensors 418, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 418 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 418 can capture a real-time video image of the surroundings proximate a user.

The visualization system 710 can include one or more video generation processors 420. The one or more video generation processors 420 can receive, from a server and/or a storage medium, scene data that represents a three-dimensional scene, such as a set of position coordinates for objects in the scene or a depth map of the scene. The one or more video generation processors 420 can receive one or more sensor signals from the one or more sensors 418. In response to the scene data, which represents the surroundings, and at least one sensor signal, which represents the location and/or orientation of the user with respect to the surroundings, the one or more video generation processors 420 can generate at least one video signal that corresponds to a view of the scene. In some examples, the one or more video generation processors 420 can generate two video signals, one for each eye of the user, that represent a view of the scene from a point of view of the left eye and the right eye of the user, respectively. In some examples, the one or more video generation processors 420 can generate more than two video signals and combine the video signals to provide one video signal for both eyes, two video signals for the two eyes, or other combinations.

The visualization system 410 can include one or more light sources 422 that can provide light for a display of the visualization system 410. Suitable light sources 422 can include any of the LEDs, pcLEDs, LED arrays, and pcLED arrays discussed above, for example those discussed above with respect to display system 300.

The visualization system 410 can include one or more modulators 424. The modulators 724 can be implemented in one of at least two configurations.

In a first configuration, the modulators 424 can include circuitry that can modulate the light sources 422 directly. For example, the light sources 422 can include an array of light-emitting diodes, and the modulators 424 can directly modulate the electrical power, electrical voltage, and/or electrical current directed to each light-emitting diode in the array to form modulated light. The modulation can be performed in an analog manner and/or a digital manner. In some examples, the light sources 422 can include an array of red light-emitting diodes, an array of green light-emitting diodes, and an array of blue light-emitting diodes, and the modulators 424 can directly modulate the red light-emitting diodes, the green light-emitting diodes, and the blue light-emitting diodes to form the modulated light to produce a specified image.

In a second configuration, the modulators 424 can include a modulation panel, such as a liquid crystal panel. The light sources 422 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 424 can include multiple modulation panels that can modulate different colors of light. For example, the modulators 424 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 424 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 410 can include one or more modulation processors 426, which can receive a video signal, such as from the one or more video generation processors 420, and, in response, can produce an electrical modulation signal. For configurations in which the modulators 424 directly modulate the light sources 422, the electrical modulation signal can drive the light sources 424. For configurations in which the modulators 424 include a modulation panel, the electrical modulation signal can drive the modulation panel.

The visualization system 410 can include one or more beam combiners 428 (also known as beam splitters 428), which can combine light beams of different colors to form a single multi-color beam. For configurations in which the light sources 422 can include multiple light-emitting diodes of different colors, the visualization system 410 can include one or more wavelength-sensitive (e.g., dichroic) beam splitters 428 that can combine the light of different colors to form a single multi-color beam.

The visualization system 410 can direct the modulated light toward the eyes of the viewer in one of at least two configurations. In a first configuration, the visualization system 410 can function as a projector, and can include suitable projection optics 430 that can project the modulated light onto one or more screens 432. The screens 432 can be located a suitable distance from an eye of the user. The visualization system 410 can optionally include one or more lenses 434 that can locate a virtual image of a screen 432 at a suitable distance from the eye, such as a close-focus distance, such as 500 mm, 750 mm, or another suitable distance. In some examples, the visualization system 410 can include a single screen 432, such that the modulated light can be directed toward both eyes of the user. In some examples, the visualization system 410 can include two screens 432, such that the modulated light from each screen 432 can be directed toward a respective eye of the user. In some examples, the visualization system 410 can include more than two screens 432. In a second configuration, the visualization system 410 can direct the modulated light directly into one or both eyes of a viewer. For example, the projection optics 430 can form an image on a retina of an eye of the user, or an image on each retina of the two eyes of the user.

For some configurations of augmented reality systems, the visualization system 410 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

As summarized above, this specification discloses display devices that may be arranged (i.e., tiled) with their display areas adjacent, in contact, and facing the same direction to form an extended continuous display area spanning the display areas of the two or more display devices. These display devices may be used for display applications (e.g., AR, VR, MR) as described above, for example. The display device comprises a front surface comprising a display area, and N≥3 sides of the display device forming an outer perimeter of the front surface. The display area extends to N−1 of the sides of the display device forming the outer perimeter of the front surface. For example, the front surface may have a quadrilateral (e.g., rectangular) shape with N=4 sides of the device defining the perimeter of the front surface, with the transparent display area extending to the outer perimeter of the front surface defined by three of the sides of the display device.

The front surface may further comprise a power and/or control electronics area arranged adjacent the transparent display area and along a portion of the perimeter of the front surface to which the display area does not extend, and electrical leads extending from the power electronics area into the transparent display area. For a rectangular front surface (N=4), for example, the display area may extend to three of the sides forming perimeters of the surface and the electronics area may be arranged between the display area and the portion of the perimeter of the front surface formed by the fourth side of the device.

The display area may comprise a microLED array that extends with the display area to physical boundaries of the device. Two or more such display devices can be combined with their display areas adjacent, in contact, and facing the same direction and with the rows and/or columns of their microLED arrays aligned to provide an extended continuous microLED array spanning the display areas of the two or more display devices. The microLEDs in the array on a display device may for example be spaced with a center-to-center pitch distance L, with the array of microLEDs extending to a distance L/2 from a physical boundary of the display device. For two such display devices combined as just described, the extended continuous microLED array spanning the display device areas of the two display devices can maintain a center-to-center pitch distance of L for adjacent microLEDs as the array crosses from one display device display area to the other.

As noted above, the display areas of the display devices may be transparent. This may be accomplished for example by using sufficiently sparse arrays of sufficiently small microLEDs arranged on a transparent substrate, with the control and power electronics arranged adjacent to the microLED array rather than behind it. Conductive paths (e.g., electrical leads) providing power and/or control signals from the power/control electronics area of a display device to the microLED arrays may be, for example, transparent or sufficiently narrow (transverse to the direction in which they extend) to not obstruct a view through the microLED array. Such a transparent display area may be, for example, at least 65% transmissive to visible light or at least 85% transmissive to visible light.

The center-to-center pitch distance in the microLEDs may be, for example, about 80 μm to about 500 μm, for example about 360 microns. The microLEDs may have side lengths in the plane off the array of, for example, about 2 microns to about 20 microns. Subsets of adjacent microLEDs in an array may be grouped as pixels, with each pixel comprising for example at least one red microLED, at least one blue microLED, and at least one green microLED. The display device may comprise, for example, 50 to 300 pixels per inch.

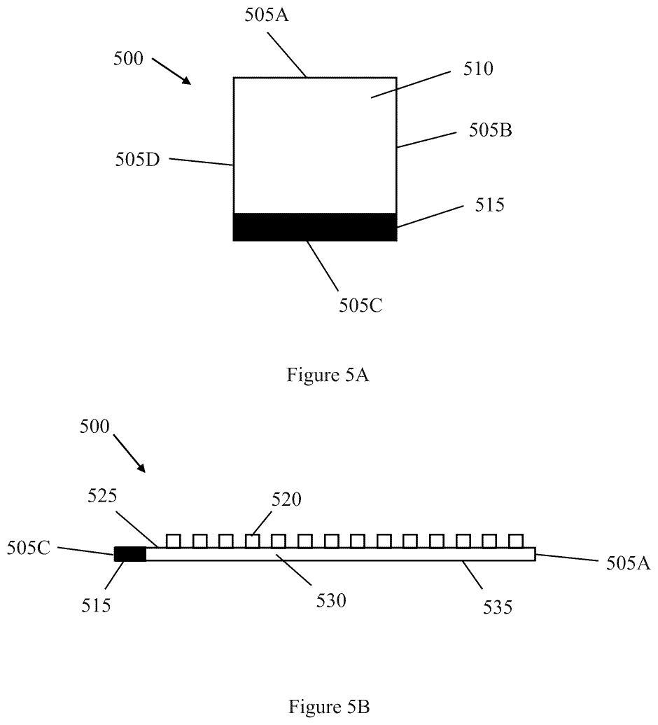

FIG. 5A schematically shows a plan view of an example tileable display device 500. Display device 500 comprises a rectangular (N=4, as discussed above) front surface having an outer perimeter defined by physical boundaries (e.g., sides) of the device 505A 505B, 505C, and 505D. The front surface of the device comprises a display area 510 that extends to three of the physical boundaries 505A, 505B and 505D of the device, and a power and/or control electronics area 515 disposed between the display area 510 and the fourth side 505C of the device.

FIG. 5B schematically shows a cross-sectional side view of example display device 500. In the illustrated example, the display area of display device 500 comprises an array of microLEDs 520 disposed on the front surface 525 of the device, arranged on a substrate 530. The array of microLEDs and the substrate may be transparent, as explained above, in which case light from behind the display device can pass through rear surface 535 of the display device and then through the display area to a person viewing the display, allowing the viewer of the display to also distinctly see objects located behind the display.

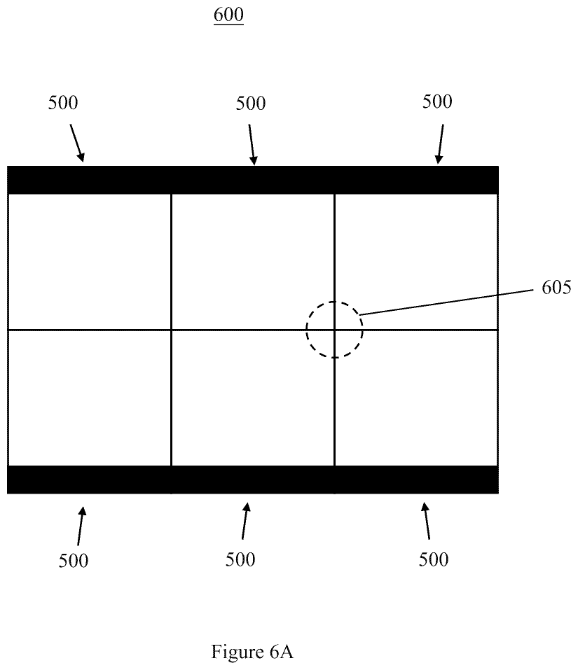

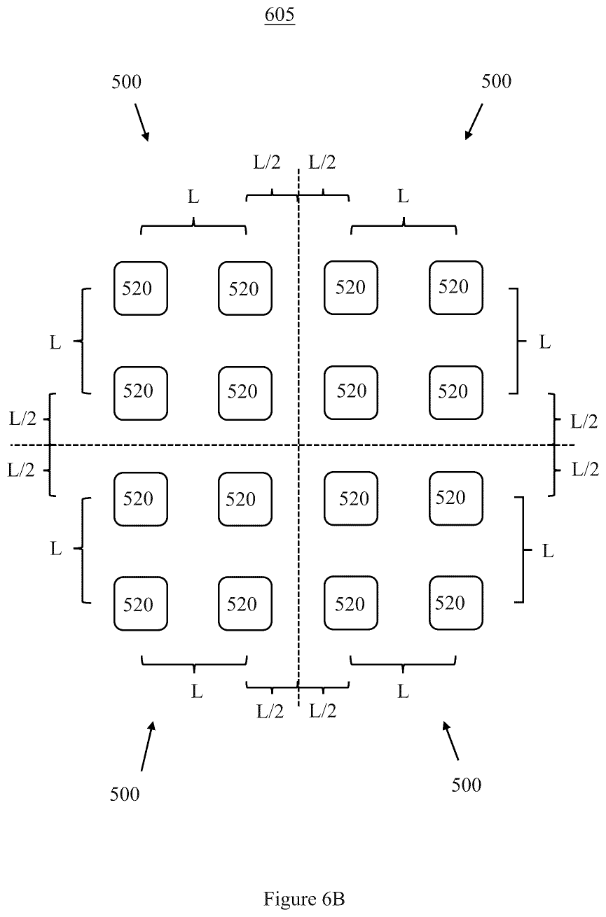

FIG. 6A schematically shows a plan view of an example display system 600 comprising six display devices 500 arranged (tiled) to form a continuous display area extending across the display areas of the six display devices. Similar such display systems may comprise two display devices arranged with their electronics areas adjacent to each other, two display devices arranged with their electronics areas arranged opposite from each other, or any suitable number of pairs of display devices arranged similarly to those in display system 600 to extend a continuous display area to any suitable length parallel to the peripherally located electronics areas.

FIG. 6B shows an expanded view of region 605 of FIG. 6A, at the intersection of the display areas of four display devices 500. In the illustrated example, the display area of each display device comprises an array of microLEDs 520 arranged with a center-to-center pitch distance L and with the array extending to a distance L/2 of a physical boundary of the display device. The rows and columns of the microLED arrays are aligned with each other to form an extended continuous microLED array spanning the display device areas of the display devices and maintaining a center-to-center pitch distance of L for adjacent microLEDs as the extended array crosses from one display device display area to another.

In the example illustrated in FIG. 6B the microLEDs are arranged with the same center-to-center pitch distance L along the rows and columns of the array, but more generally the row and column pitch distances may differ. If the row and column pitch distances differ, the microLEDs in the array may extend along rows to a distance of half the row pitch distance from a physical boundary of the display device, and along columns to a distance of half the column pitch distance from a physical boundary of the display device.

Referring again to FIG. 5A, power and/or electronics area 515 may comprise an array controller that receives instruction from a graphics card or other external source and in response provides power to microLEDs in the array to operate the array. The array may in addition or alternatively comprise transistors or microIC drivers at each pixel site that receive control signals and/or instructions from electronics area 515 and/or from a source external to the display device. More generally, any suitable control and power electronics may be used.

A display device 500 may be manufactured by, for example, preparing a transparent substrate with conductive paths (e.g., electrical leads) for the microLED array, arranging the microLEDs of the array on a transfer substrate, and then transferring the microLEDs in parallel (rather than sequentially) from the transfer substrate to the transparent substrate in registry with the conductive paths. Suitable manufacturing methods include those disclosed, for example, in U.S. Provisional Patent Application 63/420,872 filed 31 Oct. 2022, and U.S. Patent Application [[2022P00016US02]] filed, which are cited above in the Cross-Reference to Related Applications section.

As noted above, tileable transparent displays as disclosed herein may be used to construct displays for use in AR/VR/MR applications as well as for conventional display applications. The tileable transparent displays may for example be located on or incorporated into a heads-up display, an AR/VR/MR headset, vehicle windows (e.g., windshields), building windows, store display windows, other windows, or glass doors. Such displays may be used for example for advertising or to provide information about objects or a scene visible through the transparent display.

The following numbered clauses provide additional non-limiting aspects of the disclosure.

1. A display device comprising:
a front surface comprising a transparent display area; and
N≥3 sides of the display device forming an outer perimeter of the front surface, the transparent display area extending to N−1 of the sides of the display device forming the outer perimeter of the front surface.

2. The display device of clause 1, wherein the transparent display area is at least 65% transmissive for visible light.

3. The display device of clause 2, wherein the transparent display area is at least 85% transmissive for visible light.

4. The display device of clause 1, wherein the front surface comprises:
a power electronics area arranged adjacent the transparent display area and along a portion of the perimeter of the front surface to which the display area does not extend; and
electrical leads extending from the power electronics area into the transparent display area.

5. The display device of clause 4, wherein the electrical leads are transparent.

6. The display device of clause 4, wherein the electrical leads have a width less than or equal to 30 microns transverse to a direction in which they extend.

7. The display device of clause 1, wherein the display area comprises an array of microLEDs.

8. The display device of clause 7, wherein:
the microLEDs are arranged with a center-to-center pitch distance L; and
the array of microLEDs extends to a distance L/2 from the N−1 of the sides of the display device to which the transparent display area extends.

9. The display device of clause 8, wherein 80 microns≤L≤500 microns.

10. The display device of clause 9, wherein L=360 microns.

11. The display device of clause 7, wherein subsets of adjacent microLEDs are grouped into pixels, each pixel comprising at least one red microLED, at least one blue microLED, and at least one green microLED.

The display device of clause 11, comprising 50 to 300 pixels per inch.

13. The display device of clause 7, wherein the microLEDs have side lengths of 2 microns to 20 microns.

14. A display system comprising a first and a second display device as in any of clauses 1-13, arranged adjacent each other with their display areas facing a same direction and their display areas in contact with each other to form an extended continuous display area spanning the display area of the first display device and the display area of the second display device.

15. The display system of clause 14, wherein:
the first display device and the second display device each comprise a power electronics area; and
the power electronics area of the first display device is on an opposite side of the extended continuous display area from the power electronics area of the second display device.

16. The display system of clause 14, wherein:
the first display device and the second display device each comprise a power electronics area; and
the power electronics area of the first display device is adjacent the power electronics
area of the second display device.

17. A display device comprising:
a front surface comprising an array of microLEDs arranged with a center-to-center pitch distance L; and
a number of N≥3 sides of the display device forming an outer perimeter of the front surface, the array of microLEDs extending to a distance L/2 from N−1 of the sides of the display device forming the outer perimeter of the front surface.

18. The display device of clause 17, wherein the front surface comprises:
a power electronics area arranged adjacent the array of microLEDs and along a portion of the perimeter of the front surface to which array of microLEDs does not extend; and
electrical leads extending from the power electronics area into the array of microLEDs.

19. The display device of clause 17, wherein 80 microns≤L≤500 microns.

20. The display device of clause 19, wherein L=360 microns.

21. The display device of clause 17, wherein subsets of adjacent microLEDs are grouped into pixels, each pixel comprising at least one red microLED, at least one blue microLED, and at least one green microLED.

22. The display device of clause 21, comprising 50 to 300 pixels per inch.

23. The display device of clause 17, wherein the microLEDs have side lengths of 2 microns to 20 microns.

24. The display device of clause 17 comprising a transparent substrate on which the array of microLEDs is disposed.

25. The display device of clause 24, wherein the front surface comprises:
a power electronics area arranged adjacent the array of microLEDs and along a portion of the perimeter of the front surface to which array of microLEDs does not extend; and
electrical leads extending from the power electronics area into the array of microLEDs.

26. The display device of clause 25, wherein the electrical leads are transparent.

27. The display device of clause 25, wherein the electrical leads have a width less than or equal to 30 microns transverse to a direction in which they extend.

28. The display device of clause 24, wherein the array of microLEDs and the transparent substrate together are at least 65% transmissive for visible light.

29. The display device of clause 28, wherein the array of microLEDs and the transparent substrate together are at least 85% transmissive for visible light.

30. A display system comprising a first and a second display device as in any of clauses 17-29, arranged with their arrays of microLEDs adjacent to each other, facing a same direction, and forming an extended continuous array of microLEDs having a center-to-center pitch distance L.

31. The display system of clause 30, wherein:
the first display device and the second display device each comprise a power electronics area; and
the power electronics area of the first display device is on an opposite side of the extended continuous array of microLEDs from the power electronics area of the second display device.

32. The display system of clause 30, wherein:
the first display device and the second display device each comprise a power electronics area; and
the power electronics area of the first display device is adjacent the power electronics area of the second display device.

32. This disclosure is illustrative and not limiting. Further modifications will be apparent to one skilled in the art in light of this disclosure and are intended to fall within the scope of the appended claims.

What is claimed is:

1. A display device comprising:
a front surface comprising a transparent display area, the transparent display area comprising an array of microLEDs; and
three or more sides of the display device forming an outer perimeter of the front surface, the transparent display area extending to all but one of the sides of the display device forming the outer perimeter of the front surface.

2. The display device of claim 1, wherein the transparent display area is at least 65% transmissive for visible light.

3. The display device of claim 2, wherein the transparent display area is at least 85% transmissive for visible light.

4. The display device of claim 1, wherein the front surface comprises:
a power electronics area arranged adjacent the transparent display area and along a portion of the perimeter of the front surface to which the display area does not extend; and
conductive paths extending from the power electronics area into the transparent display area to power the microLEDs.

5. The display device of claim 4, wherein the conductive paths are transparent.

6. The display device of claim 4, wherein the conductive paths have a width less than or equal to 30 microns transverse to a direction in which they extend.

7. The display device of claim 1, wherein:
the array of microLEDs comprises microLEDs arranged in rows with a center-to-center pitch distance L along each row; and
microLEDs at the ends of each row are located at a distance L/2 from one of the sides of the display device to which the transparent display area extends.

8. The display device of claim 7, wherein 80 microns≤L≤500 microns.

9. The display device of claim 8, wherein L=360 microns.

10. The display device of claim 1, wherein the microLEDs are grouped into pixels, each pixel comprising at least one red microLED, at least one blue microLED, and at least one green microLED.

11. The display device of claim 10, comprising 50 to 300 pixels per inch.

12. The display device of claim 1, wherein the microLEDs have side lengths of 2 microns to microns.

13. The display device of claim 1, comprising a transparent substrate on which the array of microLEDs is disposed.

14. A display system comprising:
at least first and second display devices each comprising;
a front surface comprising a transparent display area, the transparent display area comprising an array of microLEDs,
three or more sides of the display device forming an outer perimeter of the front surface, the transparent display area extending to all but one of the sides of the display device forming the outer perimeter of the front surface; and
a power electronics area arranged adjacent the transparent display area and along a portion of the perimeter of the front surface to which the display area does not extend;
the first and second display devices arranged adjacent each other with their display areas facing a same direction and their display areas in contact with each other to form an extended continuous display area spanning the display area of the first display device and the display area of the second display device.

15. The display system of claim 14, wherein the power electronics area of the first display device is on an opposite side of the extended continuous display area from the power electronics area of the second display device.

16. The display system of claim 14, wherein the power electronics area of the first display device is adjacent to the power electronics area of the second display device.

17. The display system of claim 14, wherein:
for each display device the array of microLEDs comprises microLEDs arranged in rows with a center-to-center pitch distance L along each row, and microLEDs at the ends of each row are located at a distance L/2 from one of the sides of the display device to which the transparent display area extends; and
rows of microLEDs in the first display device are aligned with rows of microLEDs in the second display device to form continuous rows spanning the display area of the first display device and the display area of the second display device with a center-to-center pitch distance L along each such continuous row.

18. The display system of claim 14, wherein 80 microns≤L≤500 microns.

19. The display system of claim 14, wherein the microLEDs are grouped into pixels, each pixel comprising at least one red microLED, at least one blue microLED, and at least one green microLED.

20. The display system of claim 14, wherein the microLEDs have side lengths of 2 microns to 20 microns.
